(19) United States
(12) Patent Application Publication
(10) Pub. No.: US 2006/0151778 A1
(43) Pub. Date: Jul. 13, 2006

(54) Organic-inorganic hybrid transistors

(76) Inventors: Margherita Fontana, Zurich (CH); Henning Sirringhaus, Cambridge (GB); Paul Smith, Zurich (CH); Natalie Stutzmann, Eindhoven (NL); Walter Caseri, Zurich (CH)

Correspondence Address: SUGHRUE MION, PLLC, 2100 PENNSYLVANIA AVENUE, N.W., SUITE 800, WASHINGTON, DC, 20037, US

(21) Appl. No.: 10/520,131

(22) PCT Filed: Jul. 3, 2003
(86) PCT No.: PCT/GB03/02863

§ 371 Date: Oct. 5, 2005

(30) Foreign Application Priority Data
Jul. 3, 2002 (GB) 0215375.7

(51) Int. Cl. H01L 29/08

(52) U.S. Cl. 257/40

(57) ABSTRACT

A new class of organic-inorganic materials for thin film semiconducting devices that exhibit good stability in air and water, as well as a new purification technique for thin film semiconducting devices that contain impurities, such as ionic species.

This invention relates to a new class of materials, especially organic-inorganic hybrid materials, for use in electronic or optoelectronic devices; and methods of processing the materials, for example to reduce impurities by means of exposure to solvents such as for instance water. The devices may include thin film transistors. Examples of the materials exhibit good stability in water, air and light.

Semiconducting conjugated polymer field-effect transistors (FETs) have potential applications as key elements of integrated logic circuits (C. Drury, et al., APL 73, 108 (1998)) and optoelectronic devices (H. Sirringhaus, et al., Science 280, 1741 (1998)) based on solution processing on flexible plastic substrates. One main criterion to obtain high charge carrier mobilities has been found to be a high degree of structural order in the active semiconducting polymer.

Local order in thin polymer films can be achieved by making use of the tendency of some polymers to self-organise. An example is poly-3-hexylthiophene (P3HT) in which microcrystalline, lamella-type ordered structures can be formed by phase segregation of rigid main chains and flexible side chains. By using suitable deposition techniques and chemical modification of the substrate it is possible to induce preferential orientations of the ordered domains of the polymer with respect to the substrate surface. At present P3HT yields the highest known field-effect mobilities of 0.05-0.1 cm²/Vs for polymer FETs (H. Sirringhaus, et al. Science 280, 1741 (1998)). In these known devices there is no preferential, uniaxial alignment of the polymer chains in the plane of the film. The high mobilities are due to efficient interchain charge transport along the direction of close π-π stacking in the plane of the conjugated lamellae.

Realization of mass-produced, low-cost “plastic electronics” based on semi-conducting organic materials (Heeger, A. J., Rev. Mod. Phys. 73 (3), 681-700 (2001)) requires, among other qualities, ease of processing, and, more importantly, stability during fabrication and practical use of the final products. Virtually all organic polymers and oligomers that are under current scrutiny for this purpose appear to suffer from degradation upon exposure to oxygen and water, and, hence, require manufacturing conditions, as well as packaging systems such as glass, that are prone to eliminate at least some of their purported benefits.

Organic-inorganic hybrid materials have recently been proposed as possible alternatives to organic semi-conductors. Indeed, a number of interesting electronic devices have been demonstrated with materials such as those based on intercalated organic tin(II)iodide perovskites (Kagan, C. R., Mitzi. D. B. & Dimitrakopoulos, C. D., Science 286, 945-947 (1999); Chondroudis, K. & Mitzi, D. B., Chem. Mater. 11, 3028-3030 (1999)). Despite the beneficial fact that the synthesis of these materials may be carried out under convenient hydrothermal conditions, unfortunately, these materials also appear to suffer from environmental instability, manifested, for instance, in the form of deintercalation—a process that may occur already at room temperature (Mitzi, D. B., Medeiros, D. R. & Malenfant, P. R. L., Inorg. Chem. 41, 2134-2145 (2002)).

There is therefore a need for a material suitable for use in such devices and that has enhanced electronic performance and/or environmental stability.

According to one aspect of the present invention there is provided an electronic or optoelectronic device including a semiconductor material of a metal complex.

The metal complex is preferably a metal salt complex/metal complex salt.

Preferably the metal complex comprises a chain of cations and anions. The chain is preferably a linear chain. Preferably each anion and cation comprises a metal atom and the ions are bonded such that charge carriers of the metal atoms are delocalised along the chain. Preferably the ions are bonded to each other by means of the metal atoms. The metal atoms may be the same or different in each ion. Preferably the metal atoms of the cations are the same and the metal atoms of the anions are the same. Examples of the metal atoms include Pt, Pd, Au, Ag. Ni, Cu. One preferred arrangement is for ail the metal atoms to be Pt. Another preferred arrangement is for the metal atoms of one of the anions and the cations (most preferably the anions) to be Pt and the metal atoms of the other of the anions and the cations to be Pd.

Each ion suitably comprises a metal atom and ligands linked to the metal atom.

Each ion is preferably substantially planar, most preferably as regards its connections to the said metal atoms.

Preferably at least some of the ligands comprise a solubilizing moiety, for instance an alkyl chain. The alkyl chain may be branched or unbranched. The alkyl chain is most preferably (S)-3,7-dimethyloctyl. Preferably at least some of the ligands are of the form NH₂R, where R is the alkyl chain. Preferably all of the ligands of the anions are of the form NH₂R.

Preferably at least some of the ligands consist of halide atoms, most preferably Cl. Preferably all of the ligands of the cations consist of halide atoms.

Preferably all the anions are the same as each other and all the cations are the same as each other.

Preferably the length of the chain is in the range from 10 to 10,000 ions, more preferably 20 to 5000 ions. In addition to the ions as aforesaid the chain may also contain other terminating or intermediate units.

At least some of the ligands may comprise an optically active moiety, for instance a fluorescent moiety or a phosphorescent moiety.

At least some of the ligands may comprise an electron donor moiety and at least some of the other ligands comprise an electron acceptor moiety and the said moieties are arranged to interact to form donor-acceptor complexes. The electron donor moieties are preferably comprised by ligands of either the anions or cations and the electron acceptor moieties are comprised by the other of the anions and cations.

At least some of the ligands may comprise a charge transport moiety.

The said material may be soluble, preferably in an organic solvent. The said material is preferably insoluble in water.

The semiconductor material may constitute an active semiconductor region of the device. The device may be a switching device such as a transistor, particularly a FET. The device may be a light-emitting device or a photodiode.

The material is preferably of the general formula [([MaXₙ][MbYₘ])ᵣ, where:
Ma and Mb are independently in each occurrence metals;
X is such that MaXₙ is an anion, and is preferably of the form NH₂R, where R is an alkyl chain;
Y is such that MbYₘ is a cation, and is preferably a halide;
n is preferably 4;
m is preferably 4;
r is preferably in the range from 10 to 10,000, inclusive, but may be higher or lower.

The material is preferably semiconductive. Preferably all the Ma are the same and all the Mb are independently the same.

According to a second aspect of the invention there is provided the use, as a semiconductor region of an electronic or optoelectronic device, of a metal complex. The metal complex may have any of the features herein described.

According to a third aspect of the invention there is provided a method of forming a semiconductor region of an electronic or optoelectronic device, the method comprising a metal complex from solution to form the said region. The metal complex may have any of the features herein described.

According to a fourth aspect of the present invention there is provided a method of purifying a semiconductor material, the method comprising contacting the material with a solvent, preferably a polar solvent, and thereby removing impurities from the material, wherein the latter is substantially insoluble in said solvent.

Preferably the material is soluble. Preferably it is insoluble in the solvent.

The solvent is preferably water.

The step of contacting the material with the solvent is preferably a step of washing the material with the solvent.

Preferably the material comprises a metal complex. It may have any of the features herein described.

Preferably there is a step prior to the said contacting step of depositing the semiconductor material on a substrate to form a semiconductor region. The semiconductor material is preferably contacted with the solvent in situ on the substrate.

The semiconductor region suitably forms the active semiconductor region of an electronic or optoelectronic device. It is preferably defined on the substrate.

The method preferably comprises removing the solvent from the material and completing the formation of the electronic or electronic device.

Thus, one aspect of the present invention relates to a new class of materials that are most preferably solution processible and semiconducting. The materials may be suitable for thin-film transistor applications. Examples of the materials have been found to exhibit extraordinary stability when washed in water, even for prolonged periods of time at elevated temperatures. Examples of the materials include semi-conducting, metal-based chain-structures such as those comprising Pt, Pd, and others or mixtures thereof, synthesized in, for instance, aqueous media substituted with organic ligands.

The ligands may be the same or different at all occurrences. The ligands may display at least one or more of the following functions or characteristics: i.) promote solubility; ii.) be capable of forming a covalent bond with another ligand, for instance upon irradiation; iii.) display photoluminescence or other functional optical properties; iv.) be an electron-accepting (n-type) or electron-donating (p-type) semiconductor.

Such thin films can preferably be produced under ambient conditions from common organic solvents. They can preferably be exposed—without significant loss of performance—to white light and air for periods of time in excess of 6 months. Remarkably, it has been found that immersion of examples of such FETs in water of 90° C. for more than 12 hrs did not deteriorate important device characteristics, but, in fact improved, for instance, their ON-OFF switching ratios by a factor 10 and more.

A second aspect of the present invention relates to a technique that preferably allows the reduction of the level of impurities and residual dopants in a thin film semiconductor device that contains impurities, for instance ionic species. The technique is most preferably based on washing the as-deposited film or completed device in deionised water. After washing a reduction of the bulk film conductivity and a reduction in device hysteresis without significant degradation of the charge carrier mobility is achieved. This is due to a reduction in the impurity concentration in the device.

The present invention will now be described by way of example with reference to the accompanying drawings, in which:

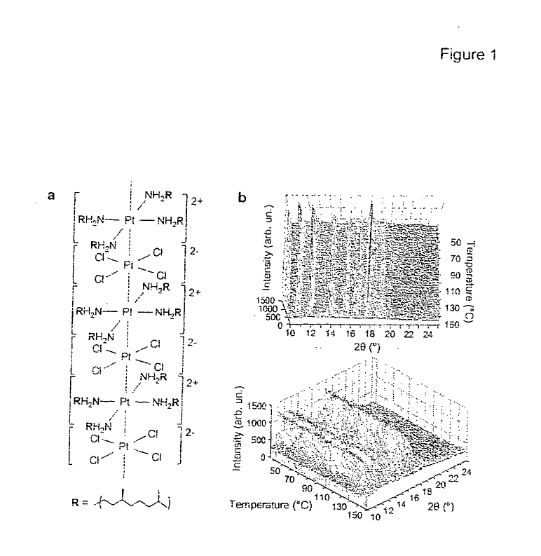

FIG. 1a is a schematic of the chemical structure of solution-processible, semi-conducting tetrakis((S)-1-amino-3,7-dimethyloctane) platinum(II)-tetrachloroplatinate (II), [Pt(NH₂dmoc)₄][PtCl₄.

FIG. 1b shows a wide-angle X-ray diffraction patterns recorded (from 2θ-10°) at the various temperatures indicated. In this dynamic experiment, the crystalline order in the Pt-compound was observed to irreversibly disappear at ˜140° C.

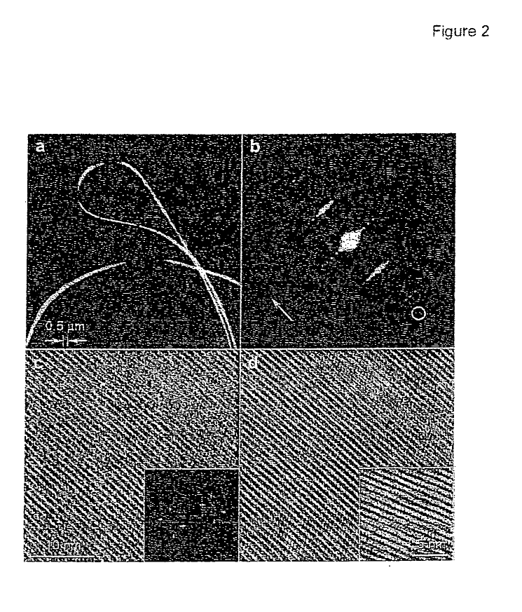

FIG. 2a is a polarized optical micrograph of an oriented filament of [Pt(NH₂dmoc)₄][PtCl₄ produced by electro-spinning from a super-cooled, viscous 45% w/w solution in toluene. Portions of the filaments that appear dark in the image are parallel to the (crossed) polarizer or analyzer.

FIG. 2b is an electron diffraction pattern revealing the orientation of the Pt-compound along the PTFE macromolecules (arrow). The open circle marks the faint reflection of the 0.1294 nm spacing along the PTFE chains.

FIGS. 2 c and d are scanning probe microscopy images revealing the very high degree of uniaxial order in the films and suggestive of the helical nature of [Pt(NH₂dmoc)₄][PtCl₄] possibly induced by the chiral ligand (S)-3,7-dimethyloctyl-1-amine, FIG. 2c is an original image taken in deflection mode: inset: fast-Fourier transform (FFT). FIG. 2d is an FFT-filtered image of FIG. 2c; inset: FFT-filtered height image. The films of FIG. 2 were grown under ambient conditions from, a 2% w/w, supersaturated solution in toluene onto a glass substrate that was coated with an ultra-thin layer of friction-deposited poly(tetrafluoroethylene). FIG. 2 b to d illustrate that films of an extraordinary degree of uniaxial crystalline order of [Pt(NH₂dmoc)₄][PtCl₄] can readily be grown.

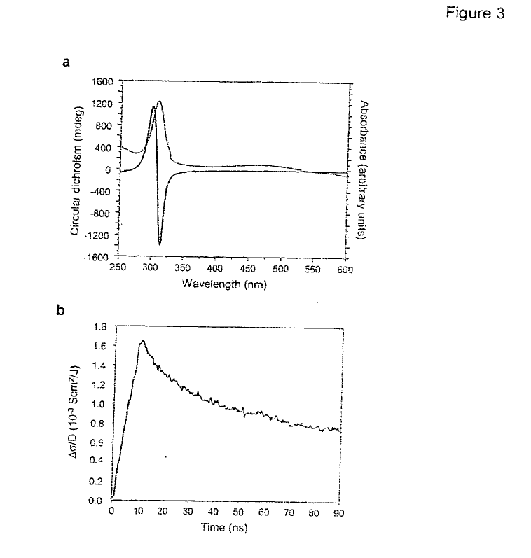

FIG. 3a is a UV-vis (dotted grey curve) and circular dichroism spectrum (solid curve) of a 1 μm film of the green Pt-compound cast from toluene. The weaker absorption band at longer wavelengths is responsible for the green colour, and is attributed to localized Pt d-d transitions.

FIG. 3b illustrates the transient change in conductivity, AG, on irradiation of [Pt(NH₂dmoc)₄][PtCl₄] with a 10 ns pulse of 3 MeV electrons detected by time-resolved microwave conductivity at a frequency of 33.5 GHz. The conductivity is normalised to the energy deposited in the sample, Δ J/cm³.

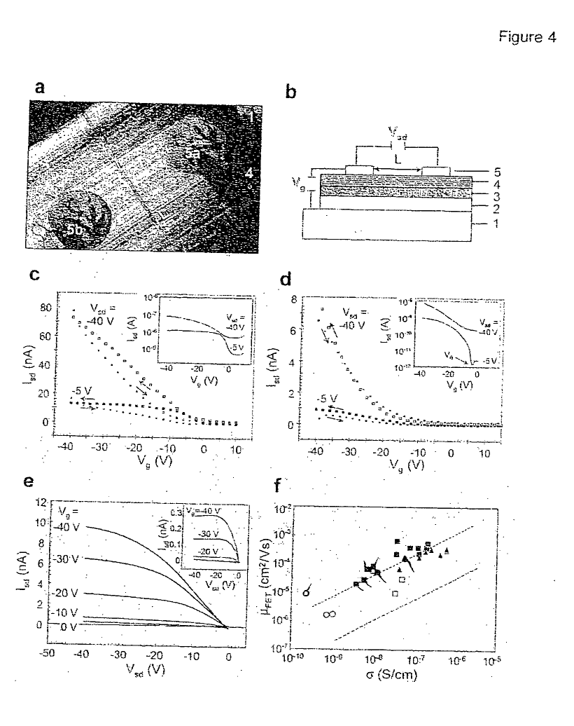

FIG. 4a is an optical micrograph of a thin-film field-effect transistor (FET), produced under ambient conditions, comprising [Pt(NH₂dmoc)₄](PtCl₄] (aligned on highly-oriented PTFE (3)) as the active semiconducting layer (4), vacuum-evaporated gold source/drain electrodes (5), and an n++-doped silicon wafer (1) with a 200-nm thin oxide layer (2) as gate and gate insulator, respectively (channel length, L=70 μm; width, W=1.5 mm; insulator capacitance, C₁=16 nF/cm²).

FIG. 4b is a schematic representation of the device of FIG. 4a.

FIG. 4c shows the transfer characteristic of the as-produced device of FIG. 4a. (Inset: Corresponding logarithmic plot).

FIG. 4d shows the transfer characteristic of the same device, but after having been stored for 12 hrs in water at 80° C., (Inset: Corresponding logarithmic plot).

FIG. 4e shows the output characteristics of (hot-)water-treated FETs, comprising highly oriented (graph) and spin-coated, unoriented (inset) (Pt(NH₂dmoc)₄][PtCl₄] active layers.

FIG. 4f shows the relationship of field-effect mobility, SFET, and conductivity, σ as determined from FET device characteristics. σ was derived from the output characteristics:

$$σ = \frac{L}{Wt} \cdot \frac{{l}_{sd} ( {V}_{g} = 0 V )}{{V}_{sd}}$$

with t, the thickness of active, semi-conducting layer. Squares and triangles represent data taken for FETs based on aligned [Pt(NH₂dmoc)₄][PtCl₄], channel parallel to Pt-chains: open squares, as-prepared devices; solid un-ticked symbols, devices of different batches after various temperature and kinetic studies, but before H₂O-bath; solid ticked symbols, devices after hot-water treatment. Open un-ticked circles are data points for devices with channel perpendicular to chains, before water storage; open ticked circle: spin-coated device, after water treatment. For comparison, the power-law relationship collected by Brown et al. [Brown, et al., Synthetic Metals 68, 65-70 (1994)] for various amorphous organic semi-conductor FETs is also shown.

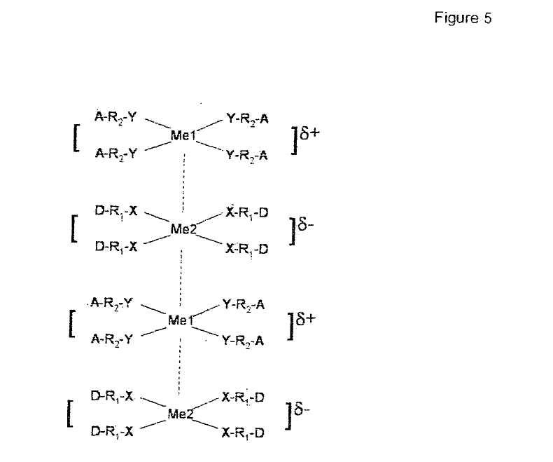

FIG. 5 shows a schematic structure of a generalised compound according to one aspect of the present invention comprising functional units D, A attached to the central metal atoms Me1, Me2 via functional groups X, Y and optional flexible linkers R₁, R₂.

One preferred example of the class of materials is illustrated in FIG. 1a. This material has a quasi-one-dimensional chain-structure with a backbone of linearly arranged platinum atoms This structure can be likened to that of Magnus' green salt, [Pt(NH₃)₄][PtCl₄], which was described as long ago as 1828 (Magnus, G., Pogg. Ann. 14, 239-242 (1828)), for an overview see Interrante, L. V., Adv. Chem. Ser. 150, 1-17 (1976). The original salt and many subsequently produced modifications thereof are characterized by a Pt—Pt distance that typically is between 0.32-0.36 nm, depending on the derivative, as opposed to 0.277 nm in platinum metal. Unfortunately, these early Pt-compounds are virtually intractable and, as a result, have found no practical applications. However, by carefully selecting the chemical structure of the ligands, e.g. NH₂R with R a linear or branched alkyl group (as shown in FIG. 1a) it has proven possible to synthesize soluble [Pt(NH₂R)₄][PtCl₄] compounds. These have been shown to exhibit a polymeric, quasi-linear Pt-chain structure even in solution and can actually be better represented as ([Pt(NH₂R)₄][PtCl₄])ₙ; with n typically varying between about 10 and 1,000, depending on the particular alkyl substituent (Bremi, J., Caseri, W. & Smith. P., J. Mater. Chem. 11, 2593-2596 (2001); Fontana, M. et al., Chem. Mat. 14, 1730-1735 (2002)). As will be described below, particularly beneficial properties have been found for the derivative in which R is (S)-3,7-dimethyloctyl (dmoc).

Synthesis of compounds of the type [Pt(NH₂R)₄][PtCl₄], which is one embodiment of the present invention, is simple in that it requires none of the special environments or particular precautions, such as exclusion of air and water, often required for the synthesis of popular organic semi-conductors. The procedure comprises dissolving K₂[PtCl₄] in water, to which the selected amino-compound is added (here (S)-3,7-dimethyloctyl-1-amine) and, subsequently, another equimolar quantity of K₂[PtCl₄], yielding the desired compound. The product is extracted from the reaction mixture simply by dissolution in, for instance, hot toluene. [Pt(NH₂dmoc)₄][PtCl₄] thus obtained is a green, crystalline material that is thermally stable in air up to above 130° C. (FIG. 1b) (for details of the synthesis see for example, Bremi et al. Chem. Mater. 11, 977 (1999)),

[Pt(NH₂dmoc)₄][PtCl₄] is highly soluble at moderately elevated temperatures (˜70-80° C.) in a variety of common organic solvents, including toluene, trichloroethane, p-dichlorobenzene and xylene, from which the Pt-compound can conveniently be recrystallized by cooling or evaporation of the solvent under ambient conditions. This very desirable property makes it possible to readily form films, fibres (FIG. 2a), blends with polymers, and other structures. Also, the growth of highly oriented films of [Pt(NH₂dmoc)₄][PtCl₄] was found to be a rather trivial exercise. When glass slides covered with a friction-deposited transfer film of polytetrafluoroethylene) (PTFE) were introduced as orienting substrate into a super-saturated toluene solution of the Pt-compound, it crystallized in the form of a film of an extraordinary high degree of uniaxial orientation along the axis of the PTFE macromolecules. From the very rich electron diffraction patterns of such films (FIG. 2b) the Pt—Pt distance was determined to be 0.31 nm, which is shorter than the spacing found in previously synthesized members of the [Pt(NH₂R)₄][PtCl₄] series and is closer to that in Pt metal. Spin-coating under ambient conditions yielded relatively amorphous films, as evidenced by polarizing optical microscopy and X-ray analysis, due to the low rate at which the complex process of self-ordering of the linear Pt-chains takes place.

UV-vis spectra of [Pt(NH₂dmoc)₄][PtCl₄] films (FIG. 3a) were found to be dominated by an absorption maximum at a wavelength λ=310 nm that was previously assigned to a 5d_{z}2-6p_{z} charge-transfer transition from the [PtCl₄]²⁻ to the [Pt(NH₂R)₄]²⁺ unit. The films displayed a distinct bisignate Cotton effect, indicative of strong excitonic coupling between the chromophores. Ultra-high chiral anisotropy factors g_{abs} (=Δε/ε of the same film at the same wavelength) of −0.11 and 0.10 were determined for the first and second Cotton effect at λ=314 and 298 nm, respectively. These values exceed those usually found for organometallic and organic substances, including certain biomolecules that have been reported to exhibit “giant” circular dichroism.

The bulk electrical conductivity at room temperature of compacted powder pellets of [Pt(NH₂dmoc)₄][PtCl₄] was 2.10⁻⁷ S/cm, which is in the range of 10⁻⁶-10⁻⁶ S/cm reported previously for many other quasi-one dimensional metal compounds, e.g. iridium, gold, nickel, and platinum complexes Including Magnus' green salt itself (Miller, J. S. & Epstein, A. J., Prog. Inorg. Chem. 20, 1-151 (1976); Rao, C. N. R. & Bhat, S. N., Inorg. Nucl. Lett. 5, 531-532 (1969)). (It should be noted that the electrical conductivity of Magnus' green salt can be significantly influenced by the presence of impurities (Mehran, F. & Interrante, L. V., Solid State Commun. 18, 1031-1034 (1976)). Reduction of the conductivity values of about a factor of 10 were recorded upon treatment of the material for 12 hrs in H₂O at 90° C.

The intrinsic mobility of charge carriers in [Pt(NH₂dmoc)₄][PtCl₄] has been determined using the pulse-radiolysis time-resolved microwave conductivity technique (PR-TRMC) (Schouten, P. G., Warman, J. M. & de Haas, M. P., J. Phys. Chem. 97, 9863-9870 (1993)). From the room temperature, transient radiation-induced conductivity shown in FIG. 3b, the one-dimensional mobility along the Pt-chains is determined to be ≧0.06 cm²/Vs. This compares favourably with values found for π-stacked discotic materials and π-bond conjugated polymers using the same technique. The mobility determined by PR-TRMC is the trap-free value and is expected to be close to the optimum value that could be achieved in a DC device structure for a welt-organized layer of the semi-conductor material between the electrodes. This has been shown to be the case for time-of-flight measurements on the discotic material hexakis(hexylthio)triphenylene and for FET measurements on α,ω-dihexylquaterthiophene. Well-aligned, defect free layers of [Pt(NH₂dmoc)₄][PtCl₄] should, therefore, ultimately be capable of sustaining current densities and switching times comparable with the best molecular semi-conductor materials presently in use or proposed.

Simple, field-effect transistors comprising [Pt(NH₂dmoc)₄][PtCl₄] as the active semi-conductor layer were produced under ambient conditions in air both with highly oriented films grown onto PTFE orientation layers and isotropic, spin-coated films of the Pt compound (FIG. 4). Devices in which the Pt-chain structures were aligned parallel to the current transport direction exhibited p-type transistor action with field-effect mobilities on the order of 10⁻³-10⁻⁴ cm²/Vs. We attribute this to injection of holes into the valence band, which is based on the Pt d_{z}² orbitals and is therefore delocalized along the polymer axis. In contrast, we were not able to obtain n-type operation. The observation of clean transistor device operation in this material is remarkable as it demonstrates that the level of mobile ionic impurities in [Pt(NH₂dmoc)₄][PtCl₄] is sufficiently low that the formation of an accumulation layer of field-induced charge carriers at the active semi-conductor/dielectric interface is possible. [Pt(RNH₂)₄][PtCl₄] compounds are a new class of organic-inorganic hybrid materials for thin film transistors.

In as-prepared devices relatively high film (bulk) conductivity on the order of 10⁻⁷ S/cm was observed (FIGS. 4c and f), limiting the ON-OFF current ratio of the transistors to less than 10 (inset in FIG. 4c). Unpackaged transistors were immersed in water at a temperature of up to 90° C. for a period of 12 hrs and more, followed by drying under vacuum for 12 hrs. For selected samples, this procedure was repeated twice. Afterwards a decrease of the film conductivity by more than one order of magnitude was observed resulting in an increase of the ON-OFF current ratio to >10²-10³ (inset FIG. 4d), and suggesting a removal of impurities, such as ionic species, by the water “washing”. In addition the hysteresis of the device characteristics between subsequent sweeps of the gate/source-drain voltage was significantly reduced. Most remarkably, the transistor devices showed no evidence of degradation demonstrating the extraordinary stability of [Pt(NH₂dmoc)₄][PtCl₄] (FIG. 4d,e). A small decrease of the field-effect mobility was noted upon water exposure, which is explained by a direct relationship between the field-effect mobility μ_{FET} and the film conductivity a of the form μ_{FET}∝σ^{α} (α≈0.7) (FIG. 4f). A similar relationship had previously been observed for doped, amorphous conjugated polymer semi-conductors (Brown, Synth. Met. 68, 65 (1994)) in which an increase of dopant concentration, i.e., bulk conductivity, enhances the hopping rate between transport sites. The small observed reduction in mobility is therefore not a sign of material degradation, but is entirely consistent with the reduction in film conductivity. It also indicates that, in contrast to the more microscopic PR-TRMC measurements, the mobility observed in FET devices is still limited by transport in disordered regions of the film, presumably grain boundaries.

Mobilities obtained for devices produced with the channel perpendicular to the oriented [Pt(NH₂dmoc)₄][PtCl₄] molecules and for those devices produced by spin-coating of an isotropic active layer onto Si/SiO₂ wafers void of PTFE orientation layers, were found to be two and three orders of magnitude lower than the above values, respectively (cf. inset FIG. 4e). This finding once again illustrates the importance of acquiring control of the structural order in the active semi-conductor layer, which is readily achieved for this Pt-chain compound.

The observation of improvement of transistor characteristics after “water washing” shows that the water treatment reduces the concentration of impurities and unintentional dopant atoms. We believe that this procedure is advantageous also for other semiconductors, where ionic impurities affect the device performance. One of the requirements for successful washing purification is a good stability and insolubility of the as-deposited semiconducting material and other layers of the device in water as well as good adhesion of the different layers of the device in order to prevent delamination during the washing step.

Many technological applications of solution-based thin film transistors such as integrated logic circuits and active-matrix displays require mobilities of 10⁻³-10⁻² cm²/Vs or higher and ON-OFF current ratios exceeding 10⁵ which have been achieved in devices comprising organic semi-conducting polymers such as poly(3-hexylthiophene) or polyfluorene derivatives (e.g. poly(fluorine-co-bithiophene) [Sirringhaus, H. et al., Appl. Phys. Lett. 77, 406-408 (2000)]. Under optimized conditions, the latter are reported to display mobilities up to 0.1 cm²Ns and 0.02 cm²/Vs, respectively. The PR-TRMC for the intrinsic mobility for the Pt-compound imply that further improvements in device performance may be achieved by, for example, additional purification, ordering of the present material and optimization of the device design. The extraordinarily simple and versatile synthesis (which permits easy incorporation of additional functionalities), convenient processibility, and outstanding resistance to relatively harsh environmental conditions, combined with the not-prohibitive cost of the principal starting material (estimated to be about one-fifth of that of substituted poly(phenylene vinylenes) and pentacene), could make compounds of the type of the present [Pt(NH₂dmoc)₄][PtCl₄] the material of choice for certain ‘sloppy’ electronic products.

In the following a detailed description of materials, thin film and device preparation as well as film characterization is given.

A detailed description of the synthesis of [Pt(NH₂dmoc)₄][PtCl₄] was previously presented [Fontana, M. et al., Chem. Mat. 14, 1730-1735 (2002)].

Time-resolved, variable temperature wide-angle X-ray scattering (WAXS) experiments were performed on the BM26B DUBBLE beamline of the European Synchrotron Radiation Facility (ESRF) in Grenoble, France. The data were collected with a curved micro-strip gas chamber detector positioned such that its centre of curvature coincided with the sample position, and in time frames of 10 s. Reflections of the α-phase of isotactic polypropylene recorded at a wavelength of 0.154 nm were used to calibrate the detector. [Pt(NH₂dmoc)₄][PtCl₄] powder was sandwiched between mica sheets and enclosed in a small aluminium sample holder (used for differential scanning calorimetry), which was placed in a modified Linkam THMS 600 hot-stage equipped with a TMS-92 controller. A heating rate of 5° C./min was used. Optical microscopy was carried out with a Leica DMRX polarizing microscope, equipped with a Mettler Toledo FP82 HT hot stage. Transmission electron microscopy (TEM) was performed with a Philips CM300 instrument operated at 200 kV under low-dose conditions selected to avoid reduction of the Pt-compounds to elemental platinum. Scanning probe microscope images were recorded in air in the contact mode with a Nanoscope E instrument (Digital instruments, Santa Barbara, Calif.), which was calibrated with muskovite mica. UV-vis spectroscopy and circular dichroism measurements were carried out on films of a thickness of about 1 μm cast onto quartz glass; a Perkin Elmer Lambda 900 instrument and Jasco J-600 spectropolarimeter were employed. Bulk conductivities were measured on pressed pellets by determining the DC resistance with two contacts clamped on each side of pressed pellets of 2 mm thickness and 10 mm diameter.

Thin films of [Pt(NH₂dmoc)₄][PtCl₄] were generally prepared by casting or spin-coating (500 rpm, 300 s (Fairschieid Technologies 1001)), from solutions comprising, respectively 0.2 and 2.0% w/w of the compound in toluene, and which were prepared by heating at 80° C. for 30 min after which a clear, green solution was obtained. Oriented growth of films of the Pt-compound was effectuated by immersing a glass substrate coated with a friction-deposited, thin layer of PTFE [Wittmann, J.-C. et al. Nature 352, 414-417 (1991)] at room temperature into a super-saturated solution of the material, prepared by dissolving 0.2% w/w of [Pt(NH₂dmoc)₄][PtCl₄] in toluene at 80° C. After approximately 2 hrs, a film of a thickness of about 100 nm had formed, remarkably, solely onto the PTFE-coated area. Electrostatic-spinning was carried out according to standard techniques by applying a voltage of 10 kV over an electrode immersed into a capillary containing a hot 45% vow solution of [Pt(NH₂dmoc)₄][PtCl₄] in toluene and a ground plate, resulting in moderately oriented filaments of the Pt-compound of lengths up to 5 mm and cross-sectional dimensions in the range from 0.1-2 μm. One set of field-effect transistors was assembled by depositing thin, aligned [Pt(NH₂dmoc)₄][PtCl₄] films on PTFE-coated Si(n⁺⁺)/SiO₂ wafers. Two gold, charge-injecting ohmic source-drain contacts were evaporated on top of the semi-conducting film using a shadow mask. For comparison, another set of devices comprising spin-coated films was fabricated from a 2% w/w toluene solution. All device characteristics were determined with a semi-conductor parameter analyzer HP 4145B at room temperature. Charge carrier mobilities μ_{FET} were extracted from the respective transfer characteristics (FIG. 4c,d) employing the relation:

$$\frac{δ {I}_{sd} ( {V}_{g} )}{δ {V}_{g}} = \frac{{C}_{i} \cdot W}{L} {μ}_{FET} ( {V}_{g} , {V}_{sd} ) \cdot ( {V}_{g} - {V}_{0} ) \qquad ( 1 )$$

where I_{sd} is the source-drain current (saturation regime), V_{g} and V_{sd} gate and source-drain voltage, respectively, Cᵢ, the insulator capacitance, W and L the channel width and length, and, V₀, the turn-on voltage (see inset FIG. 4d).

The new class of thin film organic-inorganic semiconducting devices, as well as the purification technique for thin film semiconducting devices containing impurities, such as ionic species, according to this invention are useful in the context of TFT logic circuits (C. Drury, et al., APL 73, 108 (1998)) or pixel drive transistors in high-resolution, active matrix displays (H. Sirringhaus, et al., Science 280, 1741 (1998)). Examples of such displays are active matrix polymer LED displays, liquid-crystal displays (LCD) or electrophoretic displays. The invention can also be used for the fabrication of other thin film semiconducting devices such as rectifying diodes, light emitting diodes, or photovoltaic diodes.

The ligands of the metal ions can be used to provide additional optical or electronic functionality to that of the Pt chains (see FIG. 5). For example some or all of the ligands may contain a fluorescent unit (A or B in FIG. 5) such as a fluorene unit or a phosphorescent unit, such as a metal porphyrin, that could be attached to the central Pt, Pd or other metal ion (Me1/Me2) via flexible linker XR1/YR2 units. For example X═Cl, Y═NH₂, R1, R2=CₙH₂ unit. In such a structure the Pt chains would provide semiconducting charge transport as well as optical properties while the fluorescent units would provide additional desired optical functionality, such as for example: linearly polarised fluorescent or electroluminescent properties. The self-assembling properties of the Pt chains can be used as a scaffold to build a linearly organised structure of the functional ligand molecules. Such a material has useful properties in electro-optical electronic devices, such as light-emitting devices.

Another example of functional ligands are donor-acceptor complexes which are of interest for splitting of light-generated excitons into free charges by charge transfer from the donor to the acceptor molecules. If the donor molecule was attached to the metal cation (anions and the acceptor was attached to the metal anion (cation) the self-assembling properties of the Pt chain can be used to assemble a linearly ordered, alternating chain of donor and acceptor molecules that would provide efficient charge separation upon photoexcitation while the Pt chain would provide an efficient pathway for transport of hole carriers to the electrode. Examples of acceptor molecules are perylene or C₆₀ moieties (A in FIG. 5) that are covalently attached to the Pt ion via a flexible linker such as an alkyl chain. Examples of donor molecules are phenylene or fluorene moieties (D in FIG. 5) that are covalently attached to the Pt chain via a flexible linker such as an alkyl chain. Such a material has useful properties in electrooptical electronic devices such as solar cells and photodiode devices (see for example, Shaheen, Appl. Phys. Lett. 78, 841 (2001).

Another example of functional ligands are charge transporting ligands that complement the charge transporting properties of the Pt chain. If the ligand contains an electron transporting moiety such as a perylene, C₆₀ or a copper phtalocyanine unit the resulting material can show ambipolar properties where holes are transported efficiently along the Pt backbone, and electrons are transported by electron transfer between the ligand atoms. It is also possible to incorporate a hole transporting moiety, such as a thiophene oligomer unit with n=1-12 oligomer unit into the ligands. In one preferred embodiment of the invention, the hole transporting properties of the Pt chain would be enhanced, or in the extreme case charge transport might be completely dominated by transport through the ligand units. In the latter case the self-assembling properties of the Pt chain would simply provide a scaffold to form a linearly aligned structure of hole transport units. Such a material has useful properties in electrical devices such as field-effect transistors or rectifying diodes.

The applicant hereby discloses in isolation each individual feature described herein and any combination of two or more such features, to the extent that such features or combinations are capable of being carried out based on the present specification as a whole in the light of the common general knowledge of a person skilled in the art, irrespective of whether such features or combinations of features solve any problems disclosed herein, and without limitation to the scope of the claims. The applicant indicates that aspects of the present invention may consist of any such individual feature or combination of features. In view of the foregoing description it will be evident to a person skilled in the art that various modifications may be made within the scope of the invention.

1. An electronic or optoelectronic device including a semiconductor material of a metal complex.

2. A device as claimed in claim 1, wherein the metal complex comprises a chain of cations and anions, wherein each anion and cation comprises a metal atom and the ions are bonded such that charge carriers of the metal atoms are delocalised along the chain.

3. A device as claimed in claim 2, wherein the ions are bonded to each other by means of the metal atoms.

4. A device as claimed in claim 2 or 3, wherein each ion comprises a metal atom and ligands linked to the metal atom.

5. A device as claimed in claim 4, wherein each ion is substantially planar.

6. A device, as claimed in claim 4 or 5, wherein at least some of the ligands comprise a solubilizing moiety, preferably n alkyl chain.

7. A device as claimed in claim 6, wherein the alkyl chain is a branched alkyl chain.

8. A device as claimed in claim 7, wherein the alkyl chain is (S)-3:7-dimethyloctyl.

9. A device as claimed in any of claims 6 to 8, wherein at least some of the ligands are of the form NH₂R, where R is an alkyl chain.

10. A device as claimed in claim 9, wherein all of the ligands of the anions are of the form NH₂R.

11. A device as claimed in any of claims 4 to 10, wherein at least some of the ligands consist of halide atoms.

12. A device as claimed in claim 11, wherein the halide atoms are Cl.

13. A device as claimed in claim 11 or 12, wherein all of the ligands off the cations consist of halide atoms.

14. A device as claimed in any of claims 2 to 13, wherein all the anions are the same as each other and all the cations are the same as each other.

15. A device as claimed in of claims 2 to 14, wherein the length of the chain is in the range from 10 to 10,000 ions.

16. A device as claimed in any of claims 2 to 15, wherein each of the said metal atoms is independently one of Pt, Pd, Au, Ag, Ni, Cu.

17. A device as claimed in claim 16, wherein all the said metal atoms are Pt.

18. A device as claimed in any of claims 2 to 17, wherein at least some of the ligands comprise an optically active moiety.

19. A device as claimed in claim 18, wherein the optically active functional moiety is a fluorescent moiety or a phosphorescent moiety.

20. A device as claimed in any of claims 2 to 19, wherein at least some of the ligands comprise an electron donor moiety and at least some of the other ligands comprise an electron acceptor moiety and the said moieties are arranged to interact to form donor-acceptor complexes.

21. A device as claimed in claim 20, wherein the electron donor moieties are comprised by ligands of either the anions or cations and the electron acceptor moieties are comprised by the other of the anions and cations.

22. A device as claimed in any of claims 2 to 21, wherein at least some of the ligands comprise a charge transporting moiety.

23. A device as claimed in any preceding claim, wherein the said material is soluble.

24. A device as claimed in any preceding claim wherein the semiconductor material constitutes an active semiconductor region of the device.

25. A device as claimed in any preceding claim, wherein the device is a switching device.

26. A device as claimed in any preceding claim, wherein the device is a transistor.

27. A device as claimed in any preceding claim, wherein the device is a field effect transistor.

28. A device as claimed in any of claims 1 to 24, wherein the device is a light-emitting device or a photodiode.

29. Use, as a semiconductor region of an electronic or optoelectronic device, of a metal complex.

30. Use, as a semiconductor region of an electronic or optoelectronic device, of a metal complex comprising a chain of cations and anions, wherein each anion and cation comprises a metal atom and the ions are bonded such that charge carriers of the metal atoms are delocalised along the chain.

31. A method of forming a semiconductor region of an electronic or optoelectronic device, the method comprising processing a metal complex from solution to form the said region.

32. A method of forming a semiconductor region of an electronic or optoelectronic device, the method comprising processing a metal complex from solution to form the said region, wherein said metal complex comprises a chain of cations and anions, wherein each anion and cation comprises a metal atom and the ions are bonded such that charge carriers of the metal atoms are delocalised along the chain.

33. A method of purifying a semiconductor material, the method comprising contacting the material with a solvent and thereby removing impurities from the material.

34. A method as claimed in claim 33, wherein the material is soluble.

35. A method as claimed in claim 34, wherein the material is insoluble in the solvent.

36. A method as claimed in any of claims 33 to 35, wherein the solvent is water.

37. A method as claimed in any of claims 33 to 36, wherein the material comprises a metal complex.

38. A method as claimed in claim 37, wherein the material comprises a chain of cations and anions, wherein each anion and cation comprises a metal atom and the ions are bonded such that charge carriers of the metal atoms are delocalised along the chain.

39. A method as claimed in any of claims 33 to 38, wherein prior to the said contacting step the semiconductor material is deposited on a substrate to form a semiconductor region and the semiconductor material is contacted with the solvent in situ on the substrate.

40. A method as claimed in claim 39, wherein the semiconductor region forms the active semiconductor region of an electronic or optoelectronic device.

41. A method as claimed in claim 40, comprising removing the solvent from the material and completing the formation of the electronic or electronic device.
